(19) United States
(12) Patent Application Publication
(10) Pub. No.: US 2007/0297224 A1
(43) Pub. Date: Dec. 27, 2007

(54) MOS based nonvolatile memory cell and method of operating the same

(76) Inventors: Ya-Chin King, Taipei (TW); Chrong-Jung Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/475,114

(22) Filed: Jun. 27, 2006

(51) Int. Cl. G11C 16/06; G11C 16/04; G11C 11/34

(52) U.S. Cl. 365/185.1; 365/185.28; 365/185.29; 365/185.21

(57) ABSTRACT

A non-volatile memory cell formed on a sidewall of MOS transistor and method of operating the same are disclosed. The MOS based non-volatile memory cell is formed in the n-well and compatible with CMOS processes comprising a selecting gate, two ONO spacers, a p+ source/drain, and a p extended source region and an n extended drain. To program the cell, two strategies can be taken: (1) a band to band hot electron injection can be carried out and (2) channel hot hole induced hot electron injection. To read the nonvolatile cell, a reverse read is taken. In the reading process, the biased on the selecting gate has to make sure form a channel beneath selecting gate having its narrower end contacting with a the depletion boundary due to a reverse bias exerted on the source and n-well body so that if the cell stored with electron therein, a hole current flowing from the drain to the source can be read. To erase the datum in the cell, two approaching can be carried out. One is by FN erase, the other is by band to band induced hot hole injection.

### FIELD OF THE INVENTION

The present invention relates to a nonvolatile memory structure, specifically, to a flash memory cells formed on a sidewall of a sidewall of the transistor and a method of operating the same.

### BACKGROUND OF THE INVENTION

Flash disk is a kind of nonvolatile data storage apparatus. Once the data are stored, the lifetime of the data is at least over ten years without any electric energy to keep the data therein. To access data, it needs exerts voltages at individually electrodes only depends on what the operations are. Hence, for flash disk, no mechanical vibrating problem is required to be considered. By contrast, for hard disk apparatus, a stepping motor to carry magnetic read/write head flying on the magnetic disk is necessary. Furthermore, with fast progressing of semiconductor manufacture technique, an occupation volume of a flash disk is small significantly than that of a hard disk apparatus, for the same memory capacity is concerned. Consequently, the flash disk is a kind of high portable apparatus and widely used as a thumb disk, MP3 player, PDA (personal digital assistance), mobile phone, digital still camera, and a variety of memory cards. The applications of the memory card are even more, such as memory expansion for above hand held appliance and personal computer, and home electrical appliance.

Generally, a flash memory cell includes a control gate, a floating gate, a source/drain. When a cell is programmed so that its floating gate captures electrons in it, the datum stored in the cell is called as 0 of the binary code. By contrast, the datum is called 1 if none of electrons is trapped in the floating gate during the programming.

What a big memory capacity a flash disk apparatus is, it's surely dependent on how many flash chips it stacked and each capacity of the flash chip has. The more advance of a semiconductor fabricating technique is, the more capacity a flash chip will be. For instance as a device is scaling down by one half, the memory size will be increased by about four times. For current semiconductor processes, the size of a chip about a thumb nail having a memory capacity of about one gaga bytes (1 G) is not unusual. The capacity is over a 5½ inch large hard disk at ten years ago. Surely, the hard disk apparatus is not a feeble competitor in the memory storage market. Nowadays, not only is a 2½″ hard disk commonly used in the notebook computer, but also a mini hard disk storage apparatus or MP3 player of about 1″ in size having capacity of about 60 G is developed.

Thus to avoid the flash disk being eliminated through memory storage competition, the semiconductor manufacturing engineers are not merely pursuing the device scaling down, a better device structure of a memory cell is also desired. Recently, a novel nonvolatile cell called SONOS is a successful exemplary.

FIG. 1A and FIG. 1B represent, respectively, cross-sectional views of a split gate flash 5A and a stack gate flash 5B. The common feature is the floating gate is formed of a polycrystalline silicon layer. Once the electrons are injected into the floating gate of the flash cell, the electrons will be evenly distribution in the floating gate 10. Thus, a floating gate formed of polycrystalline silicon, the cell can only store one bit datum only.

Whereas, a SONOS (semiconductor, oxide, nitride, oxide, and semiconductor) flash 20 is different. Referring to FIG. 1C, it is like a stack gate flash 5 shown in 1B). In the SONOS cell, a silicon nitride layer 23 is substitute for the poly-Si layer. Since the nitride layer 23 is enclosed by oxide cladding layers 22, 24 and all of them are a dielectric material. Therefore, a SONOS is also like a conventional transistor having an ONO layer rather than an oxide layer. However, once electrons are captured or injected into the nitride layer 23, the electrons will be confined at a localized region due to their much lower mobility the nitride layer can provide. Consequently, if the electrons are injected from the source electrode 21, then the electrons will be localized at a region 23a close to the source region 21 and if the electrons are injected from the drain electrode 24, then the electrons will be localized at a region 23b close to the drain region 24. On the other word, a device can record two bits if it is appropriate operated. The capacity of a device is thus doubled under the same semiconductor scaling technique.

### SUMMARY OF THE INVENTION

An object of the present invention is to provide a MOS based nonvolatile memory cell which is compatible with an analog CMOS

The present invention disclosed a non-volatile memory cell formed on a sidewall of MOS transistor and its operating method. The MOS based non-volatile memory cell is formed in the n-well and compatible with CMOS processes comprising a selecting gate, two ONO spacers, a p+ source/drain, and a p extended source region and an n extended drain. To program the cell, two strategies can be taken. One is by a band to band hot electron injection can be carried out. The other is by channel hot hole induced hot electron injection. To read the nonvolatile cell, a reverse read is taken. In the reading process, the biased on the selecting gate has to make sure form a channel beneath selecting gate having its narrower end contacting with a the depletion boundary due to a reverse bias exerted on the source and n-well body so that if the cell is stored with electrons therein, a hole current flowing from the drain to the source can be read. To erase the datum in the cell, two approaching can be carried out. One is by FN erase, the other is by band to band induced hot hole injection.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A illustrates a cross-sectional view of a split gate flash according to prior art.

FIG. 1B illustrates a cross-sectional view of a stack gate flash according to prior art.

FIG. 1C illustrates a cross-sectional view of a SONOS nonvolatile memory cell according to prior art.

FIG. 2A. shows a structure of pMOS based nonvolatile cell according to the present invention.

FIG. 2B. shows programming a pMOS based nonvolatile cell by band to band hot electron injection according to the present invention.

FIG. 2C shows programming a pMOS based nonvolatile cell by channel hot hole induced hot electron injection according to the present invention.

FIG. 2D shows reading a pMOS based nonvolatile cell by a reverse read method according to the present invention.

FIG. 2E shows erasing a pMOS based nonvolatile cell by FN method to pull out the electron in the nitride layer according to the present invention.

FIG. 2F shows erasing a pMOS based nonvolatile cell by band to band hot hole injection according to the present invention.

FIG. 3 shows a structure of pMOS based nonvolatile twin cells according to the present invention.

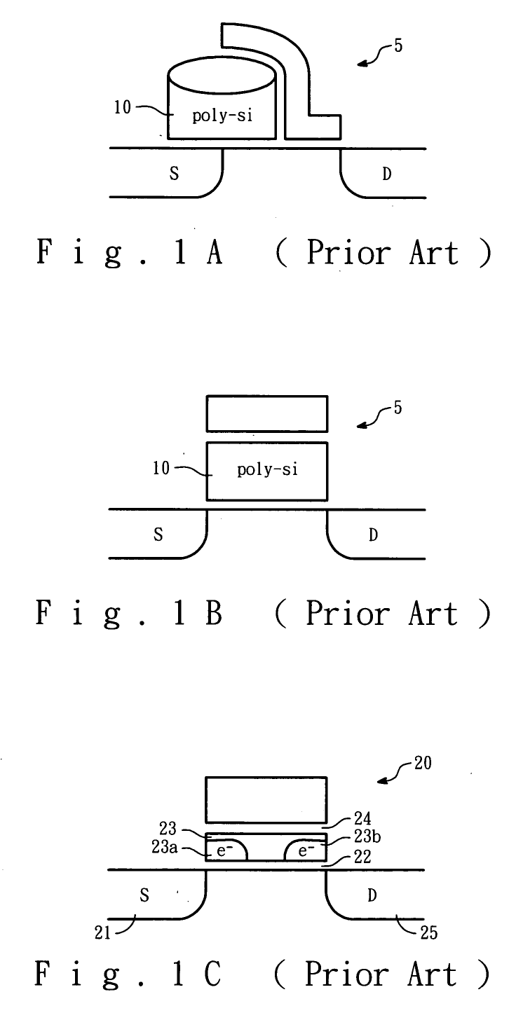

### DETAILED DESCRIPTION OF THE PREFERRED EMBODIMENT

In a preferred embodiment, the present invention is to provide a novel SONOS flash cell of which fabricating processes are completely compatible with those of analog CMOS (complementary metal oxide semiconductor transistor) processes. One of the ONO spacers served as a floating gate of a nonvolatile cell is constructed at the sidewalls of a pMOS. To operate the memory cell, the gate of the pMOS is served as a selecting gate associated with individually voltages exerted at the source/drain and the body of the pMOS.

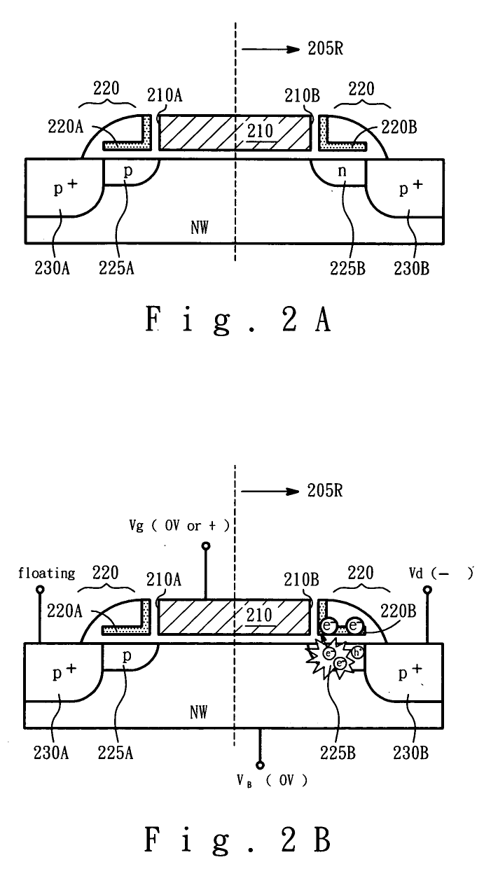

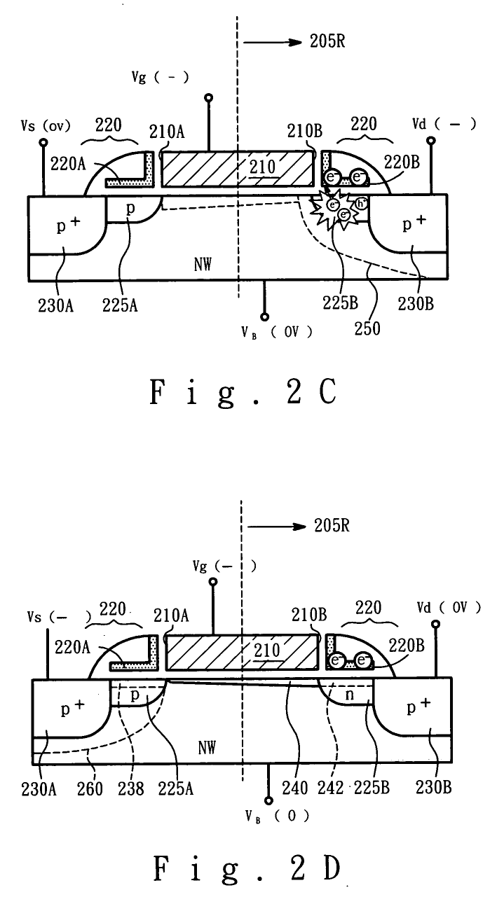

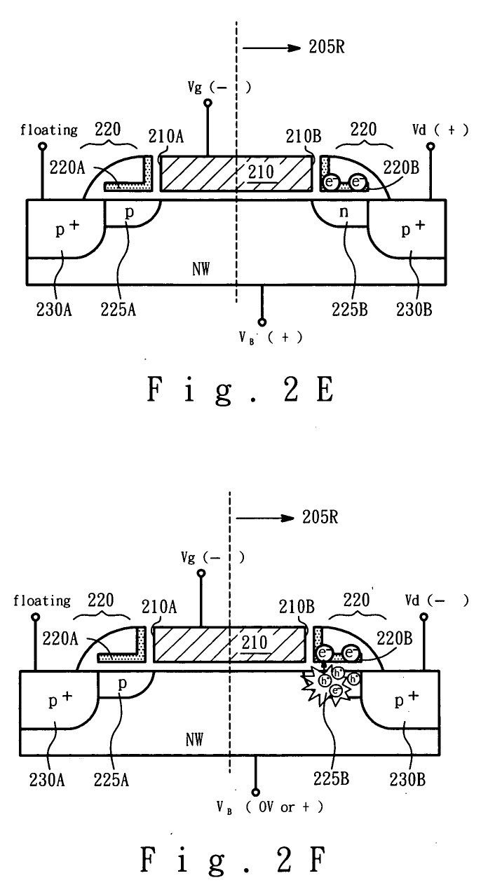

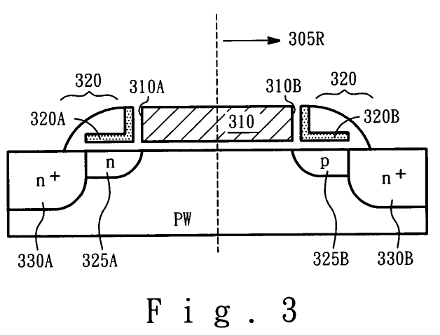

The pMOS based nonvolatile cell 205R is constructed in a n-well NW of CMOS processes. Please refer to FIG. 2A, a cross-sectional view. It includes a selected gate 210, two sidewalls 210A, 210B, ONO spacers 220 having, respectively, a L-mirror and a L shaped nitride layer 220A, 220B, a p+ doped source 230A/drain region 230B, and a p doped extended source region 225A and an n doped extended drain region 225B. The impurity concentrations in the p doped extended source225A and the extended drain, 225B are higher than that of in the n-well. Worthwhile to note, the conductivity type of the impurity in the extended drain 225B is opposite to that in the source/drain 230A, 230b and in the extended source 225. The ONO spacer 220 including the nitride layer 220B is served as a floating gate of the nonvolatile cell 205R. On the other hand, the ONO spacer 220 including the nitride layer 220A is served as a simple spacer.

For programming the right nonvolatile cell 205R, one of two approaches based on: (1)band to band hot electron injection; and (2) channel hot hole induced hot electron injection can be chosen.

Programming the cell by band to band hot electron injection:

When the cell 205R is desired to program as 1, the voltages Vs, Vg, V_{B}, and Vd exerted on the source electrode 230A, selecting gate 210, n-well body NW, and drain 230B are respectively, floated, 0V or a more positive voltage denoted by Vg((0V or +), 0V denoted by V_{B} (0V), and negative voltage denoted by Vd (−), as is shown in FIG. 2B. Accordingly, the drain 230B and the n-well body NW are reverse biased, as a result an electric field due to the space charges is generated in between the drain 230B and n-well NW. If the intensity of electric field is strong enough, electron-hole pairs are generated due to a Fermi level of the valence band of the p+ drain region 230B is over the Fermi level of the conduction band of the extended drain region 225B. The valence band electrons in the p+ drain region 230B from the filled energy level can thus tunnel through the depletion region to the empty energy level of the conduction band of extended drain region 225B left more holes in the p+ drain region 230B and more electrons in the extended drain region 225B since the extended drain region 225B has a higher impurity concentration than in the n-well NW body. The holes are attracted to the wire connected with the drain 230B due to Vd(−). The electrons are mainly toward the selecting gate due to Vg((0V or +) and the n-well NW body. On the way of electrons toward the selecting gate 210, a small cluster of electrons are captured by the nitride layer 220B of the nonvolatile cell 205R by tunneling through the oxide layer. As the nonvolatile cell 205R is desired to program as 0, the voltage exerted on it will be 0 V, i.e., Vd(0). In other words, the drain is served as a bit line while programming the nonvolatile cell 205R.

(2) Programming the cell 205R by channel hot hole induced hot electron:

Referring to FIG. 2C, assuming the cell 205R is desired to be programmed as 1, the voltages exerted on the source electrode 230A, selecting gate 210, n-well body NW, and drain 230B are respectively, 0V, −V, 0V, and −V. Due to Vg(−V), the inversion layer beneath the selecting gate 210 formed as a first channel 240 and having a tapered shaped of the first channel 240 end contacted to the boundary of a depletion region 250, which is generated due to a reverse bias at the p+ drain region 230 (Vd (−V))/ the n-well NW body (V_{B}(0V)). The Vg(−V) also makes a second channel 238 formed in the extended source region 225A formed. Consequently, the hot holes from the source region 230A through the second channel 238, first channel 240 to the depletion region 250 are accelerated by the electric field, as a result, the energetic hot holes knocked out the silicon lattice to form abound of electron-hole pairs. The positive carrier (holes) are attracted to the drain 230B due to Vd (−V), and the electrons are injected into n-well NW body and the selecting gate. Partly of lucky electrons are injected into the nitride layer 220B of the nonvolatile cell 205R.

For reading the nonvolatile cell 205R, the variety voltages Vs(−), Vg (−), V_{B} (0), and Vd (0) exerted on the electrodes are shown in FIG. 2D. The cell reading is called “reverse read.” Since the voltage Vd of the drain electrode closed to the cell 205R is Vd(0) but the voltage Vs of the source electrode 230A far from the cell 205R is Vs(−V). The Vg (−) is to generate first channel 240 and the Vs(−) applied to the source 230A associated with the voltage V_{B} (0) is to make sure the depletion boundary of the depletion region 260 connected with the tapered end of the first channel 240 so that if the floating gate, the nitride layer 220B had stored the electrons, the third channel 242 will be formed. In the situation of nitride layer 220B has electrons, a hole current can be read, which is a hole current flowing from the drain region 230B through the third channel 242, first channel 240, to the depletion region 260 and accelerated therein by the electric field, thereby into the source region 230A.

On the contrary, if the cell 205R having none electron in the nitride layer 220R, the third channel 242 is OFF, and thus no current can be read.

To erase the data in the cell of the pMOS based cell, the methods of the data erasing includes (1) FN (Fowler_Nordheim) erase, as is shown in FIG. 2E; and (2) band to band hot hole injection, as is shown in FIG. 2F.

Erasing the datum of the cell 205R by FN:

When the datum in the cell 205R is desired to be erased by FN erase, the voltages exerted on the source electrode 230A, selecting gate 210, n-well body NW, and drain 230B are respectively, floating, Vg(−), Vd (+), and V_{B}(+). In the situation, the aim of pulling out the electrons is done by Vd (+) exerted on the drain 220 R, which attracts the electrons in the nitride layer 220B.

(2) Erasing the datum of the cell 205R by band to band hot hole injection:

When the datum in the cell 205R is desired to be erased by band to band hot hole injection, the source electrode 230A is floating and the voltages are Vg(−), V_{B}(0 or +), and Vd (−), as is shown in FIG. 2E. Consequently, the drain 230B and the n-well body NW is a reverse biase, as a result, an electric field is generated in between the drain 230B and n-well NW. The electric field generated due to a reverse bias can thus generate the electron-hole pairs in the extended drain region 220B, as aforementioned paragraph about the cell 205R programming. Since the selecting gate encounters a negative voltage bias rather than a positive voltage, the holes of the electron hole pairs are thus upward to the selecting gate 210, or drain 230B, and partly, are captured by the electrons in the nitride layer 220B of the cell 205B to cause electron-hole recombination. If the nitride layer 220B has no electron, the chance of the holes injected into the nitride layer is almost zero. On the other hand, the electrons of the electron hole pairs are toward the n-well NW body.

The forgoing illustration is based on pMOS based nonvolatile cell. It is intended to cover various modifications and similar arrangements included within the spirit and scope of the appended claims, the scope of which should be accorded the broadest interpretation so as to encompass all such modifications and similar structure. For instance, the spirit and scope of the appended claims pMOS based cell should include an nMOS-based cell, as is shown in FIG. 3.

The structure of the nMOS-based cell is formed in the p-well includes: a selected gate 310, two sidewalls 310A, 310B, ONO spacers 220 having, respectively, a L-mirror and a L shaped nitride layer, 320A, 320B, an n+ doped source 330A/drain region 330B, and an n doped extended source 325A and a p extended drain region 325B.

Since the conductivity of a pMOS is opposite to the nMOS, thus the operation method will be also opposite. For example, for programming the pMOS based cell, it is based on band to band hot electron injection, whereas for nMOS based cell, the principle is band to band hot hole injection. For erasing the pMOS based cell, the principle based on band to band hot hole injection, whereas for nMOS based cell, it is band to band hot electron injection.

Table 1 shows a comparison of voltage exerted on between pMOS based twin cells and nMOS based cell for reading, programming, and erase the right cell.

| | | pMOS based | nMOS based |
|---|---|---|---|
| | | twin cells | twin cells |
| Programming | Source Vs | floating | floating |
| by (1) | selecting gate Vg | 0 V or +V | −V |
| | Drain Vd | −V | +V |
| | NW or PW V_{B} | 0 V | −V |
| Programming | source Vs | 0 | 0 |
| by (2) | selecting gate Vg | −V | +V |
| | drain Vd | −V | +V |
| | NW or PW V_{B} | 0 V | 0 V |
| Reading | source Vs | −V | +V |
| | selecting gate Vg | −V | +V |
| | drain Vd | 0 V | 0 V |
| | NW or PW V_{B} | 0 V | 0 V |
| Erase | Source Vs | floating | floating |
| method (1) | selecting gate Vg | −V | +V |
| | drain Vd | +V | −V |
| | NW or PW V_{B} | +V | −V |
| Erase | source Vs | floating | floating |
| method (2) | selecting gate Vg | −V | +V |
| | drain Vd | −V | +V |
| | NW or PW V_{B} | 0 V or +V | −V |

The benefits of this invention are:

(1) The PMOS based cell according to the present invention can be formed without extra processes.

(2) The fabricating processes are compatible with the analog CMOS processes.

As is understood by a person skilled in the art, the foregoing preferred embodiment of the present invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

What is claimed is:

1. A MOS transistor based nonvolatile cell formed in a substrate having second conductivity type impurities lightly doped, said MOS transistor based cell comprising:
a selecting gate;
a pair of ONO spacers formed on the sidewalls of said MOS transistor, said ONO spacers having a L and L-mirror shaped nitride layer to store carriers therein;
a source/drain region having first conductivity type impurities heavily doped;
an extended source region doped with said first conductivity type impurities; and
an extended drain region doped with said second conductivity type impurities, the polarity of said first conductivity type being opposite to said first conductivity.

2. The MOS transistor based nonvolatile cell according to claim 1 wherein said second conductivity type is an n-type and said first conductivity type is a p-type and said substrate is an n-well.

3. The MOS transistor based nonvolatile cell according to claim 2 wherein said MOS transistor based nonvolatile cell is programmed by a band to band hot electron injection.

4. The MOS transistor based nonvolatile cell according to claim 2 wherein said MOS transistor based nonvolatile cell is programmed by a channel hot hole induced hot electron injection.

5. The MOS transistor based nonvolatile cell according to claim 2 while reading said nonvolatile cell, said drain region is biased by Vd(0) and said selecting gate is biased by Vg(−) associated with a reverse bias on said source region and said substrate so that a first channel thereunder said selecting gate having a taper end contacts with a depletion boundary due to said reverse bias.

6. The MOS transistor based nonvolatile cell according to claim 2 while erasing the datum of said nonvolatile cell, a FN (Fowler_Nordheim) erase is taken so as to pull out the electrons in said nitride layer of said selected cell.

7. The MOS transistor based nonvolatile cell according to claim 2 while erasing the datum of said nonvolatile cell, a band to band hot hole injection is taken so as to inject holes to said nitride layer of said nonvolatile cell.

8. The MOS transistor based nonvolatile cell according to claim 1 wherein said second conductivity type is a p-type and said first conductivity type is an n-type and said substrate is a p-well.

9. The MOS transistor based nonvolatile cell according to claim 8 wherein said MOS transistor based cell is programmed by a band to band hot hole injection.

10. The MOS transistor based nonvolatile cell according to claim 8 wherein said MOS transistor based nonvolatile cell is programmed by a channel hot electron induced hot hole injection.

11. The MOS transistor based nonvolatile cell according to claim 8 while reading said nonvolatile cell, said drain region is biased by Vd(0) and said selecting gate is biased by Vg(+) associated with a reverse bias on said source region and said substrate so that a first channel thereunder said selecting gate having a taper end contacts with a depletion boundary due to said reverse bias.

12. The MOS transistor based nonvolatile cell according to claim 8 while erasing the datum of said nonvolatile cell, a FN (Fowler_Nordheim) erase is taken so as to pull out the holes in said nitride layer of said nonvolatile cell.

13. The MOS transistor based nonvolatile cell according to claim 7 while erasing the datum of a selected cell, a band to band hot electron injection is taken so as to inject electrons into said nitride layer of said nonvolatile cell.

14. A method of programming a MOS transistor based nonvolatile cell according to claim 1, is selected from method of a band to band hot electron injection to inject electrons to said nitride layer of said nonvolatile cell or method of channel hot hole induced hot electron injection when said second conductivity type is n-type.

15. A method of erasing a MOS transistor based nonvolatile cell according to claim 1, is selected from a method of (1) a band to band hot hole injection to inject holes to said nitride layer of a selected cell when said second conductivity type is n-type, or method of (2) FN (Fowler_Nordheim) erase so as to pull out the electrons in said nitride layer of said nonvolatile cell when said second conductivity type is an n-type.

16. A method of reading a MOS transistor based nonvolatile cell according to claim 1, while reading said nonvolatile cell, said drain region is biased by Vd(0) and said selecting gate is biased by Vg(−) associated with a reverse bias on said source region and said substrate so that a first channel thereunder said selecting gate having a taper end contacts with a depletion boundary due to said reverse bias.
